(19) United States
(12) Patent Application Publication
(10) Pub. No.: US 2025/0142962 A1
(43) Pub. Date: May 1, 2025

(54) ARRAY BASE PLATE AND METHOD FOR MANUFACTURING ARRAY BASE PLATE

(71) Applicant: KUNSHAN GO-VISIONOX OPTO-ELECTRONICS CO., LTD., Kunshan (CN)

(72) Inventors: Chuanzhi XU, Kunshan (CN); Zhengfang XIE, Kunshan (CN); Siming HU, Kunshan (CN); Xiaoyu GAO, Kunshan (CN)

(73) Assignee: KUNSHAN GO-VISIONOX OPTO-ELECTRONICS CO., LTD., Kunshan (CN)

(21) Appl. No.: 19/006,298

(22) Filed: Dec. 31, 2024

Related U.S. Application Data
(63) Continuation of application No. PCT/CN2022/124521, filed on Oct. 11, 2022.

(30) Foreign Application Priority Data
Aug. 25, 2022 (CN) 202211026410.4

(51) Int. Cl. H10D 86/40; H10D 86/01; H10K 59/131

(52) U.S. Cl. CPC H10D 86/481; H10D 86/021; H10D 86/441; H10K 59/131

(57) ABSTRACT

The present application discloses an array base plate and a method for manufacturing an array base plate. The array base plate includes: a substrate; a first metal layer located on a side of the substrate and including a first capacitor plate; a first insulation layer located on a side of the first metal layer away from the substrate, wherein the first insulation layer includes at least two layers, a first groove and a first via, the first groove is formed by recessing a surface of the first insulation layer away from the first metal layer, the first via penetrates through the first insulation layer; and a second metal layer located on a side of the first insulation layer away from the first metal layer and including a second capacitor plate, wherein at least a part of the second capacitor plate is located in the first groove.

### CROSS-REFERENCE TO RELATED APPLICATION

The present application is a continuation of International Application No. PCT/CN2022/124521, filed on Oct. 11, 2022, which claims priority to Chinese Patent Application No. 202211026410.4, filed on Aug. 25, 2022, and entitled “ARRAY BASE PLATE AND METHOD FOR MANUFACTURING ARRAY BASE PLATE”. The disclosures of the aforementioned applications are incorporated herein by reference in their entireties.

### TECHNICAL FIELD

The present application relates to the field of display, and particularly to an array base plate and a method for manufacturing the array base plate.

### BACKGROUND

With the rapid development of electronic devices, demands of users for the display panel are higher and higher, resulting in that the manufacturing and the display of the display panel of the electronic devices attract more and more attention in the industry.

The display panel includes an array base plate, the array base plate includes a substrate and a plurality of metal layers provided on the substrate, and different metal layers include different signal lines, such as a gate line, a scanning line, a capacitor plate, and the like. This results in that the manufacturing of the array base plate is extremely complicated, and it is necessary to pattern the metal material layers multiple times to form various signal lines, which further results in that it is difficult to ensure the yield of the array base plate.

### SUMMARY

Embodiments of the present application provide an array base plate and a method for manufacturing the array base plate, aiming to improve the yield of the array base plate. Embodiments of a first aspect of the present application provide an array base plate including: a substrate; a first metal layer located on a side of the substrate and including a first capacitor plate; a first insulation layer located on a side of the first metal layer away from the substrate, wherein the first insulation layer includes at least two layers, a first groove and a first via, the first groove is formed by recessing a surface of the first insulation layer away from the first metal layer, the first via penetrates through the first insulation layer, an orthographic projection of the first groove on the substrate at least partially overlaps an orthographic projection of the first capacitor plate on the substrate, and an orthographic projection of the first via on the substrate is spaced apart from the orthographic projection of the first capacitor plate on the substrate; and a second metal layer located on a side of the first insulation layer away from the first metal layer and including a second capacitor plate, wherein at least a part of the second capacitor plate is located in the first groove.

Embodiments of a second aspect of the present application further provide a method for manufacturing an array base plate, and the method includes:
providing a base plate to be etched, wherein the base plate to be etched includes a substrate as well as a first metal layer and a first insulation layer to be etched provided in sequence on a side of the substrate, the first metal layer includes a first capacitor plate, the first insulation layer to be etched has a first groove region and a first via region, and an orthographic projection of the first capacitor plate on the substrate at least partially overlaps an orthographic projection of the first groove region on the substrate;
providing a photoresist layer on a surface of the first insulation layer to be etched away from the first metal layer, and performing a patterning treatment on the photoresist layer to form a first etched groove and a second etched groove, wherein the first etched groove is located in the first groove region and is formed by recessing a surface of the photoresist layer away from the first insulation layer to be etched, and the second etched groove is located in the first via region and penetrates through the photoresist layer;
performing a first etching treatment on the base plate to be etched having the photoresist layer to remove at least a part of a thickness of the first insulation layer to be etched in the first via region;
performing a thinning treatment on the photoresist layer, so that the first etched groove penetrates through the photoresist layer;
performing a second etching treatment on the base plate to be etched having the photoresist layer to form an array base plate including a first insulation layer, wherein the first insulation layer includes a first groove located in the first groove region and a first via located in the first via region, the first groove is formed by recessing a surface of the first insulation layer away from the first metal layer, and the first via penetrates through the first insulation layer.

In the array base plate according to the embodiments of the present application, the array base plate includes the substrate, as well as the first metal layer, the first insulation layer, and the second metal layer provided on the substrate. The first metal layer includes the first capacitor plate, the second metal layer includes the second capacitor plate, and the first capacitor plate and the second capacitor plate can form a capacitor. The first groove is provided on the first insulation layer between the first metal layer and the second metal layer, and the second capacitor plate is located in the first groove. By adjusting the size of the first groove, the overlapped area between the second capacitor plate and the first capacitor plate can be adjusted, and thus the size of the capacitor can be adjusted, so that the accuracy for manufacturing the array base plate can be improved, thereby improving the yield of the array base plate.

### BRIEF DESCRIPTION OF THE DRAWINGS

FIG. 1 is a cross-sectional view of an array base plate according to one embodiment of the present application;

FIG. 2 is a cross-sectional view of an array base plate according to another embodiment of the present application;

FIG. 3 is a cross-sectional view of an array base plate according to yet another embodiment of the present application;

FIG. 4 is a cross-sectional view of an array base plate according to yet another embodiment of the present application;

FIG. 5 is a cross-sectional view of an array base plate according to yet another embodiment of the present application;

FIG. 6 is a cross-sectional view of an array base plate according to yet another embodiment of the present application;

FIG. 7 is a cross-sectional view of an array base plate according to yet another embodiment of the present application;

FIG. 8 is a schematic flow chart of a method for manufacturing an array base plate according to embodiments of the present application;

FIG. 9 to FIG. 21 are schematic process views of a method for manufacturing a display panel according to embodiments of the present application.

### DETAILED DESCRIPTION

Embodiments of the present application provide an array base plate and a method for manufacturing the array base plate. Various embodiments of the array base plate and the method for manufacturing the array base plate will be described below with reference to the accompanying drawings.

Embodiments of the present application provide an array base plate that may be used in a display panel, and the display panel may be an Organic Light Emitting Diode (OLED) display panel.

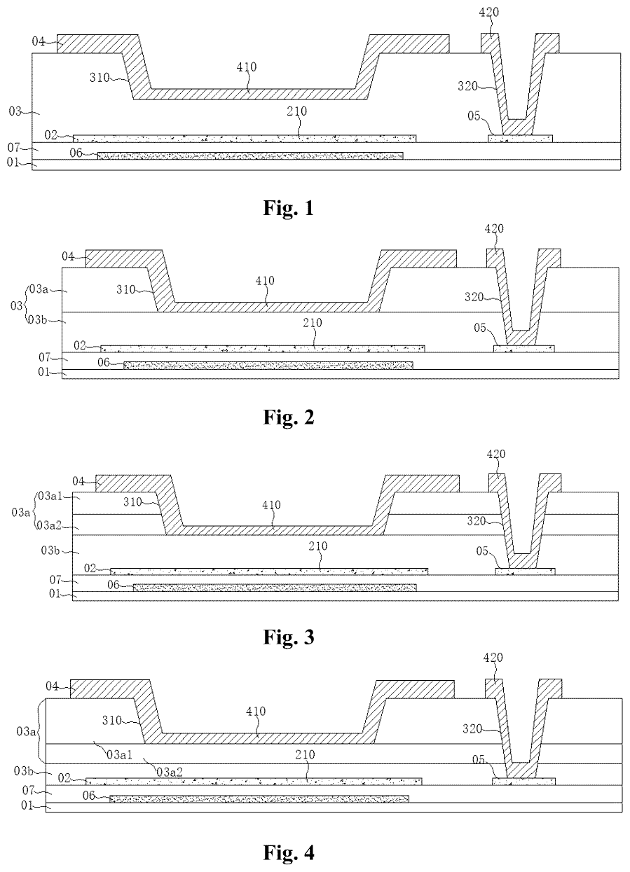

As shown in FIG. 1, embodiments of a first aspect of the present application provide an array base plate including a substrate 01, a first metal layer 02, a first insulation layer 03, and a second metal layer 04. The first metal layer 02 is located on a side of the substrate 01 and includes a first capacitor plate 210. The first insulation layer 03 is located on one side of the first metal layer 02 away from the substrate 01, the first insulation layer 03 includes a first groove 310 and a first via 320, the first groove 310 is formed by recessing a surface of the first insulation layer 03 away from the first metal layer 02, the first via 320 penetrates through the first insulation layer 03, an orthographic projection of the first groove 310 on the substrate 01 at least partially overlaps an orthographic projection of the first capacitor plate 210 on the substrate 01, and an orthographic projection of the first via 320 on the substrate 01 is spaced apart from the orthographic projection of the first capacitor plate 210 on the substrate 01; and a second metal layer 04 is located on a side of the first insulation layer 03 away from the first metal layer 02 and includes a second capacitor plate 410, and at least a part of the second capacitor plate 410 is located in the first groove 310. In the array base plate according to the embodiments of the present application, the array base plate includes the substrate 01, as well as the first metal layer 02, the first insulation layer 03, and the second metal layer 04 provided on the substrate 01. The first metal layer 02 includes the first capacitor plate 210, the second metal layer 04 includes the second capacitor plate 410, and a capacitor can be formed between the first capacitor plate 210 and the second capacitor plate 410. The first groove 310 is provided on the first insulation layer 03 between the first metal layer 02 and the second metal layer 04, and the second capacitor plate 410 is located in the first groove 310. By adjusting the size of the first groove 310, the overlapped area between the second capacitor plate 410 and the first capacitor plate 210 can be adjusted, and thus the size of the capacitor can be adjusted, so that the accuracy for manufacturing the array base plate can be improved, thereby improving the yield of the array base plate.

The substrate 01 may be made of light-transmitting materials such as glass or polyimide (PI).

The array base plate is provided in various manners. In some embodiments, the array base plate 100 may include a semiconductor layer, the first metal layer 02, the second metal layer 04, and the third metal layer which are stacked on a side of the substrate 01. An insulation layer is provided between adjacent metal layers. In an example, a pixel driving circuit provided on the array base plate includes a transistor and a storage capacitor C. The transistor includes a semiconductor, a gate, a source, and a drain. The storage capacitor C includes the first capacitor plate 210 and the second capacitor plate 410. As an example, the gate and the first capacitor plate 210 may be located on the first metal layer 02, the second capacitor plate 410 may be located on the second metal layer 04, and the source and the drain may be located on the third metal layer.

The first insulation layer 03 is provided in various manners. Optionally, the first insulation layer 03 includes at least two layers.

In some optional embodiments, with reference to FIG. 2, the first insulation layer 03 at least includes a first film layer 03a and a second film layer 03b located on a side of the first film layer 03a facing the first metal layer 02, the first groove 310 penetrates through the first film layer 03a or a part of the first film layer 03a, and the first via 320 includes a first segment penetrating through the first film layer 03a and a second segment penetrating through at least a part of the second film layer 03b.

In these optional embodiments, the first insulation layer 03 includes the first film layer 03a and the second film layer 03b, the first groove 310 is provided in the first film layer 03a, and the first via 320 penetrates through the first film layer 03a and the second film layer 03b. In a procedure for manufacturing the array base plate, the first via 320 may be manufactured by forming different segments thereof. For example, firstly, a first segment penetrating through the first film layer 03a is manufactured, then the first groove 310 is manufactured. While the first groove 310 is manufactured, a second segment penetrating through the second film layer 03b is manufactured at the position of the first segment penetrating through the first film layer 03a to form the first via 320. Therefore, a process for manufacturing the array base plate can be simplified, and problems such as the complicated manufacturing process, the low manufacturing efficiency, and the like caused by manufacturing the first via 320 and the first groove 310 separately can be mitigated.

Optionally, the array base plate further includes signal lines 420 including, for example, a data line, a scanning line, a power line, a voltage reference line, a connection line connecting a pixel electrode and the driving circuit, and these signal lines 420 may be connected through the first via 320.

For example, in some optional embodiments, as shown in FIG. 1 or FIG. 2, a connection portion 05 is provided on a side of the first via 320 facing the substrate 01, and the signal line 420 is connected to the connection portion 05 through the first via 320 to improve the yield of the signal line 420. The connection portion 05 may be located on the first metal layer 02 or the semiconductor layer.

In some embodiments, as described above, the array base plate includes the connection portion 05 located on a side of the first insulation layer 03 away from the second metal layer 04, an orthographic projection of the first via 320 on the substrate 01 at least partially overlaps an orthographic projection of the connection portion 05 on the substrate 01, and the second metal layer 04 further includes the signal line 420, the signal line 420 is electrically connected to the connection portion 05 through the first via 320. In these optional embodiments, the signal line 420 may include segments located on two sides of the first via 320, and the two segments are connected to each other through the connection portion 05, that is, the signal line 420 includes two parts respectively provided on two sides of the first via 320 in the plane where the second metal layer 04 is located, and the two parts are connected to each other through the connection portion 05, so that the yield of the signal line 420 can be improved.

In some optional embodiments, as shown in FIG. 1 or FIG. 2, the connection portion 05 is provided on the first metal layer 02, and an etching duration of the second segment of the first via 320 is the same as an etching duration of the first groove 310.

In these optional embodiments, after the first segment of the first via 320 is etched and formed, since the etching duration of the second segment of the first via 320 is the same as the etching duration of the first groove 310, the first groove 310 and the second segment of the first via 320 may be etched at the same time, thereby simplifying the process for manufacturing the array base plate. In addition, since the connection portion 05 is located on the first metal layer 02, after the etching of the second segment of the first via 320 is completed, the connection portion 05 can be exposed from the first via 320, so that the signal line 420 can be connected to the connection portion 05 by the first via 320.

The etching duration of the second segment of the first via 320 is the same as the etching duration of the first groove 310 means that the etching duration of the second segment of the first via 320 is the same as the etching duration of the first groove 310 under the same etching parameter.

The first groove 310 is provided in various manners, for example, as shown in FIG. 2, the first groove 310 may penetrate through the first film layer 03a, and specifically, the bottom wall surface of the first groove 310 may be the surface of the second film layer away from the substrate.

In some embodiments, a thickness and a material of the first film layer 03a are the same as a thickness and a material of the second film layer 03b, then the etching duration of the second segment of the first via 320 is the same as the etching duration of the first groove 310 under the same etching parameter.

Or in some other embodiments, the thickness and the material of the first film layer 03a are different from the thickness and the material of the second film layer 03b, and the first film layer 03a and the second film layer 03b satisfy the following equation (1):

$${H}_{1} / {V}_{1} = {H}_{2} / {V}_{2} \qquad ( 1 )$$

H₁ is a depth of the first groove 310, V₁ represents a speed for etching the first film layer 03a, H₂ is a thickness of the second film layer 03b, and V₂ represents a speed for etching the second film layer 03b.

V₁ and V₂ represent the speed for etching the first film layer 03a and the speed for etching the second film layer 03b under the same etching parameter.

In these optional embodiments, the thickness and the material of the first film layer 03a are different from the thickness and the material of the second film layer 03b, therefore the speed for etching the first film layer 03a is different from the speed for etching the second film layer 03b under the same etching parameter. Under a condition that the thickness of the first film layer 03a, the speed for etching the first film layer 03a, the thickness of the second film layer 03b, and the speed for etching the second film layer 03b satisfy the above relationship (1), the etching duration of the first groove 310 is the same as the etching duration of the second segment of the first via 320, and the first groove 310 and the second segment of the first via 320 may be manufactured at the same time in the same process step.

The first film layer 03a is provided in various manners, for example, the first film layer 03a may include two or more sub-layers, and the first groove 310 may penetrate through at least one of the sub-layers.

In some optional embodiments, as shown in FIG. 3, the first film layer 03a includes a first sub-layer 03a1 and a second sub-layer 03a2 located on a side of the first sub-layer 03a1 facing the substrate 01.

Under a condition that the first film layer 03a includes the first sub-layer 03a1 and the second sub-layer 03a2, the first groove 310 is provided in various manners, for example, with further reference to FIG. 3, the first groove 310 penetrates through the first sub-layer 03a1 and the second sub-layer 03a2, and the second film layer 03b, the first sub-layer 03a1, and the second sub-layer 03a2 satisfy the following equation (2):

$${H}_{11} / {V}_{11} + {H}_{12} / {V}_{12} = {H}_{2} / {V}_{2} \qquad ( 2 )$$

H₁₁ represents a thickness of the first sub-layer 03a1, V₁₁ represents a speed for etching the first sub-layer 03a1, H₁₂ represents a thickness of the second sub-layer 03a2, V₁₂ represents a speed for etching the second sub-layer 03a2, H₂ is a thickness of the second film layer 03b, and V₂ represents a speed for etching the second film layer 03b.

V₁₁, V₁₂, and V₂ represent the speeds for etching the first sub-layer 03a1, the second sub-layer 03a2, and the second film layer 03b under the same etching parameter.

In these optional embodiments, the first film layer 03a includes a two-layer structure, the first sub-layer 03a1 and the second sub-layer 03a2, and the first groove 310 penetrates through the first sub-layer 03a1 and the second sub-layer 03a2. Under a condition that the thickness of the first sub-layer 03a1, the speed for etching the first sub-layer 03a1, the thickness of the second sub-layer 03a2, the speed for etching the second sub-layer 03a2, the thickness of the second film layer 03b, and the speed for the second film layer 03b satisfy the above relationship (2), the etching duration of the first groove 310 is the same as the etching duration of the second segment, and the first groove 310 and the second segment may be manufactured at the same time in the same process step.

In some other embodiments, as shown in FIG. 4, the first groove 310 penetrates through the first sub-layer 03a1, and the bottom of the first groove 310 is located on the second sub-layer 03a2, that is, the bottom wall surface of the first groove 310 is the surface of the second sub-layer 03a2 away from the second film layer 03b. Then the second film layer 03b and the first sub-layer 03a1 satisfy the following equation (3):

$${H}_{11} / {V}_{11} = {H}_{2} / {V}_{2} \qquad ( 3 )$$

H₁₁ represents a thickness of the first sub-layer 03a1, V₁₁ represents a speed for etching the first sub-layer 03a1, H₂ is a thickness of the second film layer 03b, and V₂ represents a speed for etching the second film layer 03b.

In these optional embodiments, the first groove 310 penetrates through only the first sub-layer 03a1 and does not penetrate through the second sub-layer 03a2, and under a condition that the second film layer 03b and the first sub-layer 03a1 satisfy the above relationship (3), the etching duration of the first groove 310 is the same as the etching duration of the second segment of the first via 320, and the first groove 310 and the second segment of the first via 320 may be manufactured at the same time in the same process step.

In yet some other embodiments, the etching duration of the first groove 310 may be different from the etching duration of the second segment of the first via 320, for example, the etching duration of the first groove 310 may be greater than the etching duration of the second segment of the first via 320. Specifically, with further reference to FIG. 4, the first groove 310 penetrates through the first sub-layer 03a1, and the bottom wall surface of the first groove 310 is the surface of the second sub-layer 03a2 away from the second film layer 03b. The second film layer 03b and the first sub-layer 03a1 may satisfy the following equation (4):

$${H}_{11} / {V}_{11} = {H}_{12} / {V}_{12} + {H}_{2} / {V}_{2} \qquad ( 4 )$$

H₁₁ represents a thickness of the first sub-layer 03a1, V₁₁ represents a speed for etching the first sub-layer 03a1, H₁₂ represents a thickness of the second sub-layer 03a2, V₁₂ represents a speed for etching the second sub-layer 03a2, H₂ is a thickness of the second film layer 03b, and V₂ represents a speed for etching the second film layer 03b.

It should be noted that the equation (3) is different from the following equation (4) in that:
The first film layer 03a and the second film layer 03b need to satisfy the equation (3) under a condition that the manufacturing is performed according to the following process: firstly, the first sub-layer 03a1 and the second sub-layer 03a2 are penetrated through in a first via region where the first via 320 is located, then the first groove 310 is manufactured, and while the first groove 310 is manufactured, the second film layer 03b is penetrated through in the first via region to form the first via 320 in the first via region.

The first film layer 03a and the second film layer 03b need to satisfy the equation (4) under a condition that the manufacturing is performed according to the following process: firstly, only the first sub-layer 03a1 is penetrated through in the first via region where the first via 320 is located, then the first groove 310 is manufactured, and while the first groove 310 is manufactured, the second sub-layer 03a2 and the second film layer 03b are penetrated through in the first via region to form the first via 320 in the first via region.

In some other embodiments, the connection portion 05 may further be provided on other film layers. For example, as shown in FIG. 5, the array base plate further includes a first conductive layer 06 and a second insulation layer 07, the first conductive layer 06 is located on a side of the first metal layer 02 facing the substrate 01, and the connection portion 05 is provided on the first conductive layer 06; the second insulation layer 07 is located between the first conductive layer 06 and the first metal layer 02, and further includes a second via 710 communicating with the first via 320, the second via 710 penetrates through the second insulation layer 07, an orthographic projection of the second via 710 on the substrate 01 at least partially overlaps the orthographic projection of the connection portion 05 on the substrate 01, and an etching duration of the first groove 310 is equal to a sum of an etching duration of the second segment and an etching duration of the second via 710.

Optionally, the first conductive layer 06 may be the above semiconductor layer. Or the first conductive layer 06 may be a new conductive layer of a metal material added between the semiconductor layer and the first metal layer 02. Or the first conductive layer 06 may be a new conductive layer of a metal material added between the semiconductor layer and the substrate 01.

In these optional embodiments, the connection portion 05 is not located on the first metal layer 02, the second insulation layer 07 is further provided between the connection portion 05 and the second metal layer 04, and the second via 710 is provided on the second insulation layer 07, so that the signal line 420 can be connected to the connection portion 05 through the first via 320 and the second via 710.

In addition, the etching duration of the first groove 310 is equal to the sum of the etching duration of the second segment and the etching duration of the second via 710, so that the first groove 310, the second segment, and the second via 710 may be manufactured in the same process step, and the method for manufacturing the array base plate can be simplified.

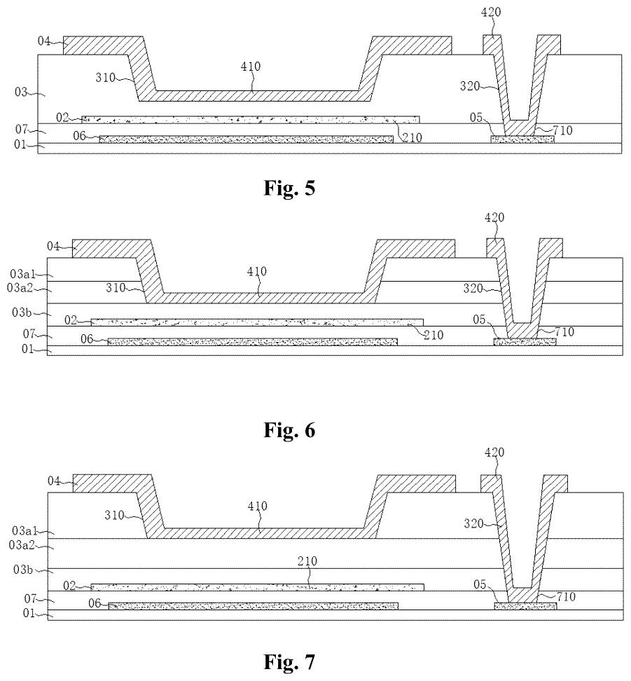

The first film layer 03a is provided in various manners, and as shown in FIG. 6, the first film layer 03a may include a first sub-layer 03a1 and a second sub-layer 03a2 located on a side of the first sub-layer 03a1 facing the substrate 01.

Under a condition that the first film layer 03a includes the first sub-layer 03a1 and the second sub-layer 03a2, the first groove 310 may penetrate through only the first sub-layer 03a1, or the first groove 310 may penetrate through both the first sub-layer 03a1 and the second sub-layer 03a2.

In some optional embodiments, as shown in FIG. 6, the first groove 310 penetrates through the first sub-layer 03a1 and the second sub-layer 03a2, and the second film layer 03b, the first sub-layer 03a1, the second sub-layer 03a2, and the second insulation layer 07 satisfies the following equation (5):

$${H}_{11} / {V}_{11} + {H}_{12} / {V}_{12} = {H}_{2} / {V}_{2} + {H}_{3} / {V}_{3} \qquad ( 5 )$$

H₁₁ represents a thickness of the first sub-layer 03a1, V₁₁ represents a speed for etching the first sub-layer 03a1, H₁₂ represents a thickness of the second sub-layer 03a2, V₁₂ represents a speed for etching the second sub-layer 03a2, H₂ is a thickness of the second film layer 03b, V₂ represents a speed for etching the second film layer 03b, H₃ is a thickness of the second insulation layer 07, and V₃ represents a speed for etching the second insulation layer 07.

V₁₁, V₁₂, V₂, and V₃ represent the speeds for etching the first sub-layer 03a1, the second sub-layer 03a2, the second film layer 03b, and the second insulation layer 07 under the same etching condition.

In these optional embodiments, under a condition that the second film layer 03b, the first sub-layer 03a1, the second sub-layer 03a2, and the second insulation layer 07 satisfy the above relationship (5), the first groove 310, the second segment, and the second via 710 may be manufactured in the same process step, and the method for manufacturing the array base plate can be simplified.

In some other embodiments, as shown in FIG. 7, the first groove 310 penetrates through the first sub-layer 03a1, and the bottom of the first groove 310 is the surface of the second sub-layer 03a2 away from the second film layer 03b, and the second film layer 03b, the first sub-layer 03a1, and the second insulation layer 07 satisfy the following equation (6):

$${H}_{11} / {V}_{11} = {H}_{2} / {V}_{2} + {H}_{3} / {V}_{3} \qquad ( 6 )$$

H₁₁ represents a thickness of the first sub-layer 03a1, V₁₁ represents a speed for etching the first sub-layer 03a1, H₂ is a thickness of the second film layer 03b, V₂ represents a speed for etching the second film layer 03b, H₃ is a thickness of the second insulation layer 07, and V₃ represents a speed for etching the second insulation layer 07.

In these optional embodiments, under a condition that the second film layer 03b, the first sub-layer 03a1, and the second insulation layer 07 satisfy the above relationship (6), the first groove 310, the second segment of the first via 320, and the second via 710 may be manufactured in the same process step, and the method for manufacturing the array base plate can be simplified.

Under a condition that the first conductive layer 06 is the semiconductor layer, the second insulation layer 07 may be a gate insulation layer.

In any of the above embodiments, various materials are provided for the first sub-layer 03a1 and the second sub-layer 03a2, for example, the material of the first sub-layer 03a1 is different from the material of the second sub-layer 03a2. Thus, under a condition that the first groove 310 penetrates through the first sub-layer 03a1 but does not penetrate through the second sub-layer 03a2, the first sub-layer 03a1 can be etched and the etching effect on the second sub-layer 03a2 can be reduced during the manufacturing of the array base plate by setting different etching parameters.

Optionally, the material of the first sub-layer 03a1 is the same as the material of the second film layer 03b, so that an etching duration of the first sub-layer 03a1 can be the same as an etching duration of the second film layer 03b under the same etching parameter, thereby facilitating the manufacturing of the array base plate.

Optionally, the speed for etching the second sub-layer 03a2 is greater than the speed for etching the first sub-layer 03a1. In these optional embodiments, under a condition that the first sub-layer 03a1 is etched to form the first groove 310, the second sub-layer 03a2 and the second insulation layer 07 need to be etched to form the second via 710. The speed for etching the second sub-layer 03a2 is greater than the speed for etching the first sub-layer 03a1, so that an etching duration of the second sub-layer 03a2 is less. Under a condition that the first sub-layer 03a1 is etched to form the first groove 310, and at the same time the second sub-layer 03a2 and the second insulation layer 07 are etched to form the second segment and the second via 710, the etching of the first sub-layer 03a1 has not been completed after the etching of the second sub-layer 03a2 is completed. Therefore, the first sub-layer 03a1 and the second insulation layer 07 may be continuously etched, and finally the first groove 310, the second via 710, and the second segment of the first via 320 are formed at the same time.

Various materials are provided for the first film layer 03a and the second film layer 03b, for example, the materials of the second film layer 03b and the first sub-layer 03a1 include silicon oxide, and the material of the second sub-layer 03a2 includes silicon nitride; or the materials of the second film layer 03b and the first sub-layer 03a1 include silicon nitride, and the material of the second sub-layer 03a2 includes silicon oxide.

In these optional embodiments, the material of the first sub-layer 03a1 is different from the material of the second sub-layer 03a2, and the first sub-layer 03a1 and the second sub-layer 03a2 may be etched in different steps by setting etching parameters. The material of the second film layer 03b is the same as the material of the first sub-layer 03a1, so that in the same step, the materials of the second film layer 03b and the first sub-layer 03a1 may be etched, and the first groove 310 and the second segment of the first via 320 may be formed.

In some embodiments, the thickness of the second film layer 03b is greater than the thickness of the first sub-layer 03a1. For example, under a condition that the material of the second film layer 03b is the same as the material of the first sub-layer 03a1, and the first groove 310 and the second segment of the first via 320 are formed through etching in the same process step, the first groove 310 may further be formed in the second sub-layer 03a2. Therefore, a depth of the first groove 310 can be increased, a distance between the bottom of the first groove 310 and the first capacitor plate 210 can be reduced, and a capacitance of the capacitor formed between the first capacitor plate 210 and the second capacitor plate 410 can be increased.

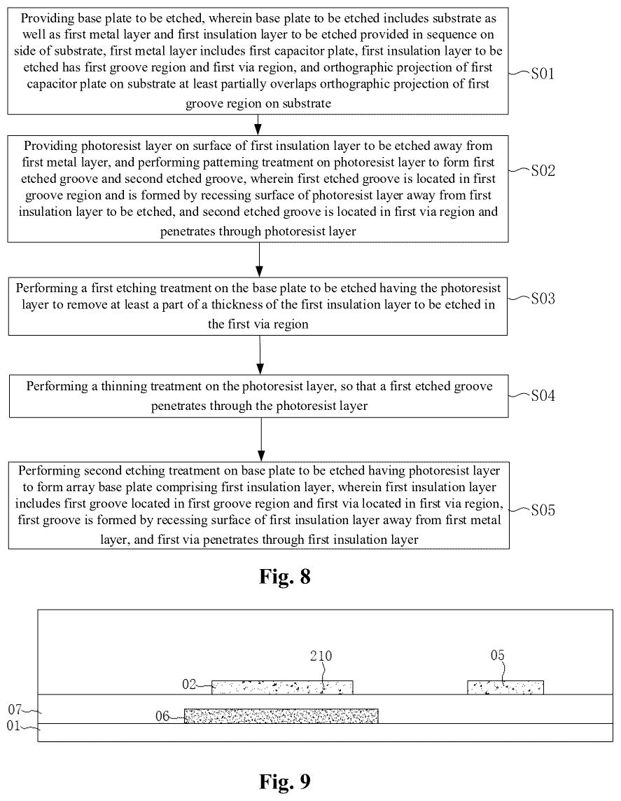

With reference to FIG. 8, FIG. 8 is a schematic flow chart of a method for manufacturing an array base plate according to embodiments of a second aspect of the present application.

As shown in FIG. 8, the second aspect of the present application further provides a method for manufacturing an array base plate which may be the array base plate in any of the above embodiments. As shown in FIG. 8, the method for manufacturing the array base plate includes:

Step S01: as shown in FIG. 9, providing a base plate to be etched, wherein the base plate to be etched includes a substrate 01 as well as a first metal layer 02 and a first insulation layer to be etched provided in sequence on a side of the substrate 01, the first metal layer 02 includes a first capacitor plate 210, the first insulation layer to be etched has a first groove region and a first via region, and an orthographic projection of the first capacitor plate 210 on the substrate 01 at least partially overlaps an orthographic projection of the first groove region on the substrate 01.

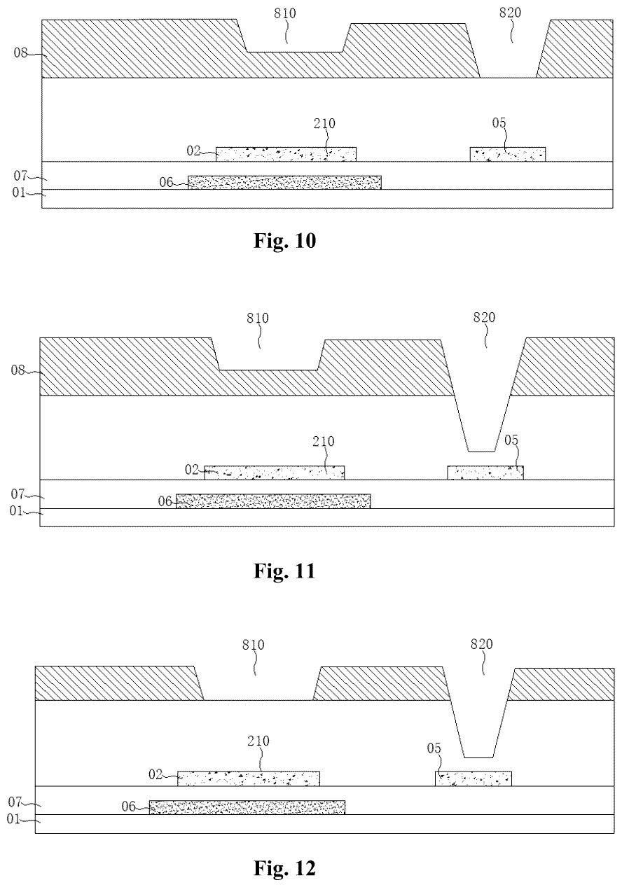

Step S02: as shown in FIG. 10, providing a photoresist layer 08 on a surface of the first insulation layer to be etched away from the first metal layer 02, and performing a patterning treatment on the photoresist layer 08 to form a first etched groove 810 and a second etched groove 820, wherein the first etched groove 810 is located in the first groove region and is formed by recessing a surface of the photoresist layer 08 away from the first insulation layer to be etched, and the second etched groove 820 is located in the first via region and penetrates through the photoresist layer 08.

Step S03: as shown in FIG. 11, performing a first etching treatment on the base plate to be etched having the photoresist layer 08 to remove at least a part of a thickness of the first insulation layer to be etched in the first via region. In other words, performing a first etching treatment on the base plate to be etched having the photoresist layer 08 to remove at least a part of the first insulation layer to be etched in the first via region.

Step S04: as shown in FIG. 12, performing a thinning treatment on the photoresist layer 08, so that the first etched groove 810 penetrates through the photoresist layer 08.

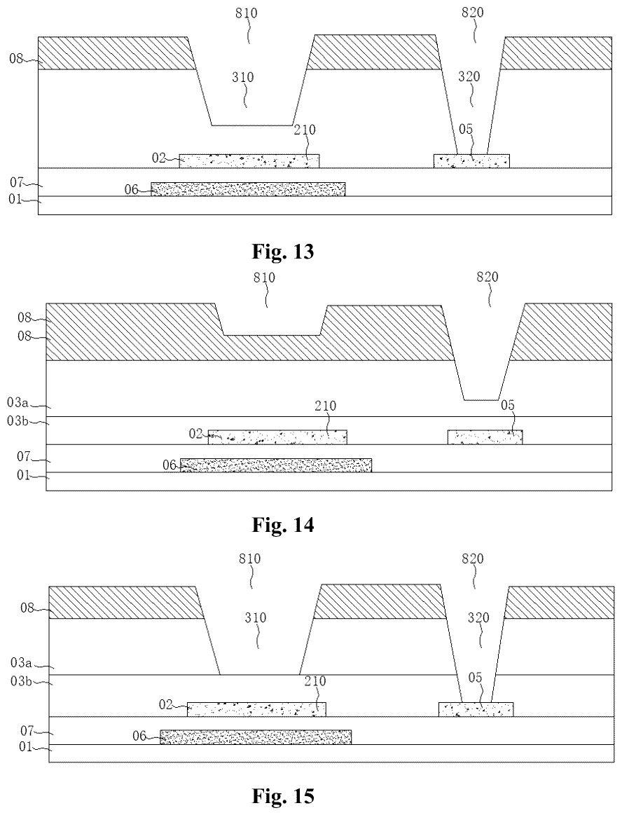

Step S05: as shown in FIG. 13, performing a second etching treatment on the base plate to be etched having the photoresist layer 08 to form an array base plate including a first insulation layer 03, wherein the first insulation layer 03 includes a first groove 310 located in the first groove region and a first via 320 located in the first via region, the first groove 310 is formed by recessing a surface of the first insulation layer 03 away from the first metal layer 02, and the first via 320 penetrates through the first insulation layer 03.

In the method for manufacturing the array base plate according to the embodiments of the present application, in step S02, the photoresist layer 08 is firstly provided on the surface of the first base plate to be etched, and then the patterning treatment is performed on the photoresist, so that at least a part of the first insulation layer to be etched can be removed in the first via region subsequently in the first etching treatment in step S03. Then a second treatment, that is, the thinning treatment, is performed on the photoresist in step S04, after the thinning treatment, the thickness of the photoresist is reduced, resulting in that the first groove 810 can penetrate through the photoresist layer 08. Next, the second etching treatment is performed in step S05, during the second etching process, the first groove 310 is formed in the first etched groove 810, and the first via 320 is formed in the second etched groove 820. Accordingly, the etching procedure of the first groove 310 and the first via 320 needs only one photoresist coating procedure, and it is not necessary to perform the coating and the removing of the photoresist layer 08 repeatedly, so that the process for manufacturing the array base plate can be simplified, and the manufacturing efficiency of the array base plate can be improved.

In addition, as described above, in the array base plate manufactured by the above manufacturing method, the second capacitor plate 410 may be provided in the first groove 310, and the effective overlapped area between the second capacitor plate 410 and the first capacitor plate 210 may be adjusted by controlling the position of the first groove 310, so that the capacitor parameter is changed, and the yield of the array base plate is improved.

In some optional embodiments, as shown in FIG. 14, for example, the first insulation layer to be etched includes the first film layer 03a and the second film layer 03b located on a side of the first film layer 03a facing the first metal layer 02. Then, in step S03, under a condition that the first etching treatment is performed on the base plate to be etched, a part of the first film layer 03a in the first via region may be removed, a thickness of the part of the first film layer 03a is n₁*H₁, n₁ is a coefficient greater than 0 and less than 1, and H₁ is a thickness of the first film layer 03a. As shown in FIG. 15, in step S05, under a condition that the second etching treatment is performed on the base plate to be etched, at least a part of the first film layer 03a in the first groove region is removed to form the first groove 310, and a remaining part of the first film layer 03a and the second film layer 03b in the first via region are removed to form the first via 320 penetrating through the first film layer 03a and the second film layer 03b, a thickness of the remaining part of the first film layer 03a is (1−n₁)*H₁.

In these optional embodiments, the part of the first film layer 03a having the thickness of n₁*H₁ is removed firstly, and the first groove 310, the remaining part of the first film layer 03a having the thickness of (1−n₁)*H₁, and the second film layer 03b are formed in the second etching treatment, that is, the first groove 310 and the first via 320 are formed, so that the process for manufacturing the array base plate can be simplified, and the manufacturing efficiency of the array base plate can be improved.

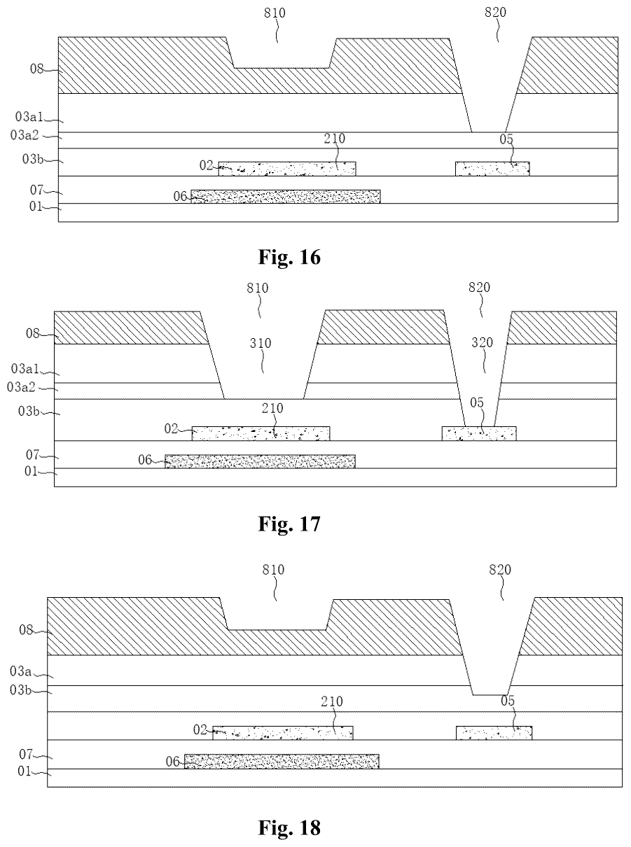

As described above, and with reference to FIG. 16, the first film layer 03a may include the first sub-layer 03a1 and the second sub-layer 03a2 located on a side of the first sub-layer 03al facing the substrate 01, and the thickness of the first sub-layer 03a1 is n₁*H₁; as shown in FIG. 16, in step S03, in the step of performing the first etching treatment on the base plate to be etched, the first sub-layer 03a1 is removed to form the first segment of the first via 320. As shown in FIG. 17, in step S05, in the step of performing the second etching treatment on the base plate to be etched, a part or all of the first sub-layer 03a1 in the first groove region is removed, or the first sub-layer 03a1 and at least a part of the second sub-layer 03a2 in the first groove region are removed, so as to form the first groove 310; and the second sub-layer 03a2 and the second film layer 03b in the first via region are removed to form the first via 320 penetrating through the first film layer 03a and the second film layer 03b. That is, the first groove 310 and the second segment are formed at the same time in step S05, and the second segment and the first segment form the first via 320. The first groove 310 and the second segment can be manufactured in the same process step, so that the process for manufacturing the array base plate can be simplified, and the manufacturing efficiency of the array base plate can be improved.

In some other optional embodiments, as shown in FIG. 18, under a condition that the first insulation layer to be etched includes the first film layer 03a and the second film layer 03b located on a side of the first film layer 03a facing the first metal layer 02, in step S03, in the step of performing the first etching treatment on the base plate to be etched, the first film layer 03a and the second film layer 03b with a thickness of n₂*H₂ in the first via region are removed, n₂ is a coefficient greater than 0 and less than 1, and H₂ is a thickness of the second film layer 03b, that is, the first film layer 03a and a part of the second film layer 03b in the first via region are removed, and a thickness of the part of the second film layer 03b is n₂*H₂. In step S05, in the step of performing the second etching treatment on the base plate to be etched, at least a part of the first film layer 03a in the first groove region is removed to form the first groove 310, and the second film layer 03b with a thickness of (1−n₂)*H₂ in the first via region is removed to form the first via 320 penetrating through the first film layer 03a and the second film layer 03b, that is, a remaining part of the second film layer 03b in the first via region is removed, and a thickness of the remaining part of the second film layer 03b is (1−n₂)*H₂.

In these optional embodiments, in step S03, all of the first film layer 03a and a part of the second film layer 03b in the first via region may be removed, and in step S05, the first film layer 03a in the first groove region may be removed to form the first groove 310, and the remaining part of the second film layer 03b in the first via region may be removed to form the second via 710.

Optionally, the second film layer 03b includes a third sub-layer 03b1 and a fourth sub-layer 03b2 located on a side of the third sub-layer 03b1 facing the substrate 01, and a thickness of the fourth sub-layer 03b2 is n₂*H₂;

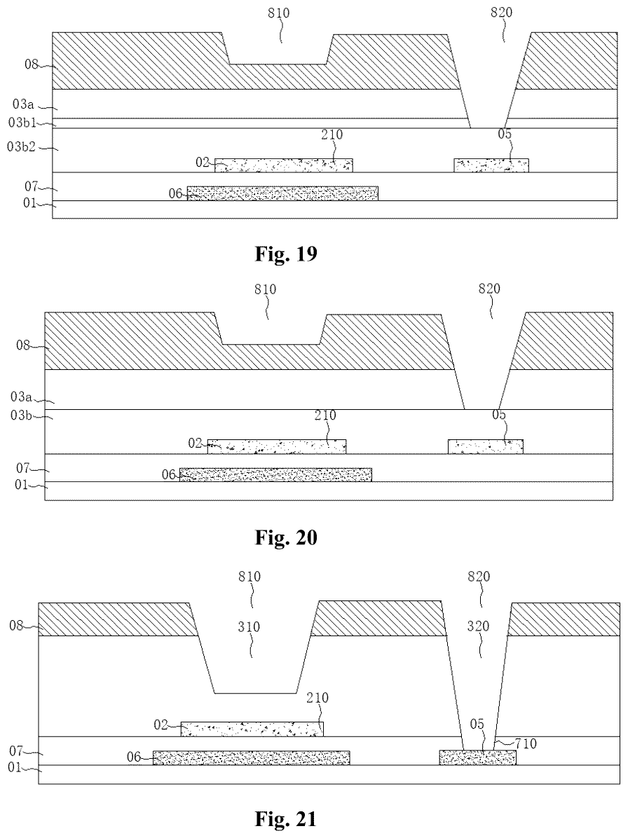

As shown in FIG. 19, in step S03, in the step of performing the first etching treatment on the base plate to be etched, the first film layer 03a and the third sub-layer 03b1 in the first via region are removed. In step S05, in the step of performing the second etching treatment on the base plate to be etched, at least a part of the first film layer 03a in the first groove region is removed to form the first groove 310, and the fourth sub-layer 03b2 in the first via region is removed to form the first via 320 penetrating through the first film layer 03a and the second film layer 03b.

Under a condition that the second film layer 03b includes the third sub-layer 03b1 and the fourth sub-layer 03b2, the first film layer 03a and the third sub-layer 03b1 in the first via region may be removed in step S03. The fourth sub-layer 03b2 in the first via region is continuously removed to form the first via 320 in step S04.

In some other optional embodiments, as shown in FIG. 20, under a condition that the first insulation layer to be etched includes the first film layer 03a and the second film layer 03b located on a side of the first film layer 03a facing the first metal layer 02, the first film layer 03a in the first via region may further be removed in step S03. In step S05, at least a part of the first film layer 03a in the first groove region may further be removed to form the first groove 310, and the second film layer 03b in the first via region may be removed to form the first via 320 penetrating through the first film layer 03a and the second film layer 03b.

In these optional embodiments, the first segment and the second segment of the first via 320 are formed in step S03 and step S05, respectively, and in step S05 the first groove 310 is manufactured while the second segment is formed, so that the process for manufacturing the array base plate can be simplified, and the manufacturing efficiency of the array base plate can be improved.

In these optional embodiments, the first film layer 03a may further include the first layer and the second sub-layer 03a2 on a side of the first sub-layer 03a1 facing the substrate 01.

Optionally, as described above, the array base plate further includes the connection portion 05, and as shown in FIG. 9 to FIG. 20, under a condition that the connection portion 05 is located on the first metal layer 02, in step S05, the first groove 310 is formed in the first groove region, and the remaining part of the first insulation layer to be etched in the first via region is removed to form the first via 320, so that the connection portion 05 can be exposed from the first via 320. Under a condition that the metal material is subsequently deposited on the first insulation layer to be etched to form the second metal layer 04, at least a part of the metal material can fall into the first via 320, so as to be connected to the connection portion 05.

In some other embodiments, as shown in FIG. 21, under a condition that the array base plate includes the first conductive layer 06 and the second insulation layer 07, the first conductive layer 06 is located on a side of the first metal layer 02 facing the substrate 01 and provided with the connection portion 05 located in the first via region, and the second insulation layer 07 is located between the first conductive layer 06 and the first metal layer 02, step S05 further includes: removing the second insulation layer 07 in the first via region to form the second via 710 penetrating through the second insulation layer 07, so that the connection portion 05 can be exposed from the first via 320 and the second via 710. The interconnection of the signal line 420 and the connection portion 05 is facilitated.

The above embodiments of the present application do not exhaustively describe all the details, nor do they limit the present application to the specific embodiments as described. Obviously, according to the above description, many modifications and changes can be made. These embodiments are selected and particularly described in the specification to better explain the principles and practical applications of the present application, so that a person skilled in the art is able to utilize the present application and make modifications based on the present application. The present application is limited only by the claims and the full scope and equivalents of the claims.

What is claimed is:

1. An array base plate, comprising:
a substrate;
a first metal layer located on a side of the substrate and comprising a first capacitor plate;
a first insulation layer located on a side of the first metal layer away from the substrate, wherein the first insulation layer comprises a first groove and a first via, the first groove is formed by recessing a surface of the first insulation layer away from the first metal layer, the first via penetrates through the first insulation layer, an orthographic projection of the first groove on the substrate at least partially overlaps an orthographic projection of the first capacitor plate on the substrate, and an orthographic projection of the first via on the substrate is spaced apart from the orthographic projection of the first capacitor plate on the substrate; and
a second metal layer located on a side of the first insulation layer away from the first metal layer and comprising a second capacitor plate, wherein at least a part of the second capacitor plate is located in the first groove.

2. The array base plate according to claim 1, wherein the first insulation layer comprises a first film layer and a second film layer located on a side of the first film layer facing the first metal layer, the first groove penetrates through the first film layer or a part of the first film layer, and the first via comprises a first segment penetrating through the first film layer and a second segment penetrating through at least a part of the second film layer.

3. The array base plate according to claim 2, further comprising a connection portion located on a side of the first insulation layer away from the second metal layer, wherein the orthographic projection of the first via on the substrate at least partially overlaps an orthographic projection of the connection portion on the substrate, the second metal layer further comprises a signal line, the signal line is electrically connected to the connection portion through the first via, and the first film layer comprises a first sub-layer and a second sub-layer located on a side of the first sub-layer facing the substrate.

4. The array base plate according to claim 3, wherein the connection portion is provided on the first metal layer, and an etching duration of the second segment is the same as an etching duration of the first groove.

5. The array base plate according to claim 4, wherein the first groove penetrates through the first film layer, and a thickness and a material of the first film layer are the same as a thickness and a material of the second film layer.

6. The array base plate according to claim 4, wherein a thickness and a material of the first film layer are different from a thickness and a material of the second film layer, and the first film layer and the second film layer satisfy the following equation (1):
$${H}_{1} / {V}_{1} = {H}_{2} / {V}_{2} \qquad ( 1 )$$
wherein H₁ is a depth of the first groove, V₁ represents a speed for etching the first film layer, H₂ is a thickness of the second film layer, and V₂ represents a speed for etching the second film layer.

7. The array base plate according to claim 4, wherein the first groove penetrates through the first sub-layer and the second sub-layer, and the second film layer, the first sub-layer, and the second sub-layer satisfy the following equation (2):
$${H}_{11} / {V}_{11} + {H}_{12} / {V}_{12} = {H}_{2} / {V}_{2} \qquad ( 2 )$$
wherein H₁₁ represents a thickness of the first sub-layer, V₁₁ represents a speed for etching the first sub-layer, H₁₂ represents a thickness of the second sub-layer, V₁₂ represents a speed for etching the second sub-layer, H₂ is a thickness of the second film layer, and V₂ represents a speed for etching the second film layer.

8. The array base plate according to claim 4, wherein the first groove penetrates through the first sub-layer, and a bottom wall surface of the first groove is a surface of the second sub-layer away from the second film layer, and the second film layer and the first sub-layer satisfy the following equations (3) or (4):
$${H}_{11} / {V}_{11} = {H}_{2} / {V}_{2} \qquad ( 3 )$$
$${H}_{11} / {V}_{11} = {H}_{12} / {V}_{12} + {H}_{2} / {V}_{2} \qquad ( 4 )$$
wherein H₁₁ represents a thickness of the first sub-layer, V₁₁ represents a speed for etching the first sub-layer, H₁₂ represents a thickness of the second sub-layer, V₁₂ represents a speed for etching the second sub-layer, H₂ is a thickness of the second film layer, and V₂ represents a speed for etching the second film layer.

9. The array base plate according to claim 3, further comprising:
a first conductive layer located on a side of the first metal layer facing the substrate, wherein the connection portion is provided on the first conductive layer; and
a second insulation layer located between the first conductive layer and the first metal layer, wherein the second insulation layer further comprises a second via communicating with the first via, the second via penetrates through the second insulation layer, and an orthographic projection of the second via on the substrate at least partially overlaps the orthographic projection of the connection portion on the substrate;
wherein an etching duration of the first groove is equal to a sum of an etching duration of the second segment and an etching duration of the second via.

10. The array base plate according to claim 9, wherein the first groove penetrates through the first sub-layer and the second sub-layer; and
the second film layer, the first sub-layer, the second sub-layer, and the second insulation layer satisfy the following equation (5):
$${H}_{11} / {V}_{11} + {H}_{12} / {V}_{12} = {H}_{2} / {V}_{2 +} {H}_{3} / {V}_{3} \qquad ( 5 )$$
wherein H₁₁ represents a thickness of the first sub-layer, V₁₁ represents a speed for etching the first sub-layer, H₁₂ represents a thickness of the second sub-layer, V₁₂ represents a speed for etching the second sub-layer, H₂ is a thickness of the second film layer, and V₂ represents a speed for etching the second film layer, H₃ is a thickness of the second insulation layer, and V₃ represents a speed for etching the second insulation layer.

11. The array base plate according to claim 9, wherein the first groove penetrates through the first sub-layer, and a bottom of the first groove is located on the second sub-layer, and the second film layer, the first sub-layer, and the second insulation layer satisfy the following equation (6):
$${H}_{11} / {V}_{11} = {H}_{2} / {V}_{2} + {H}_{3} / {V}_{3} \qquad ( 6 )$$
wherein H₁₁ represents a thickness of the first sub-layer, V₁₁ represents a speed for etching the first sub-layer, H₂ is a thickness of the second film layer, V₂ represents a speed for etching the second film layer, H₃ is a thickness of the second insulation layer, and V₃ represents a speed for etching the second insulation layer; a depth of the first groove is equal to the thickness of the first sub-layer.

12. The array base plate according to claim 9, wherein the first conductive layer is a semiconductor layer, the semiconductor layer further comprises a semiconductor portion, and the second insulation layer is a gate insulation layer.

13. The array base plate according to claim 3, wherein a material of the first sub-layer is different from a material of the second sub-layer; and
the material of the first sub-layer is the same as a material of the second film layer.

14. The array base plate according to claim 3, wherein a speed for etching the second sub-layer is greater than a speed for etching the first sub-layer;
and a thickness of the second film layer is greater than a thickness of the first sub-layer.

15. The array base plate according to claim 3, wherein materials of the second film layer and the first sub-layer comprise silicon oxide, and a material of the second sub-layer comprises silicon nitride; or materials of the second film layer and the first sub-layer comprise silicon nitride, and a material of the second sub-layer comprises silicon oxide.

16. A method for manufacturing an array base plate, comprising:
providing a base plate to be etched, wherein the base plate to be etched comprises a substrate as well as a first metal layer and a first insulation layer to be etched provided in sequence on a side of the substrate, the first metal layer comprises a first capacitor plate, the first insulation layer to be etched has a first groove region and a first via region, and an orthographic projection of the first capacitor plate on the substrate at least partially overlaps an orthographic projection of the first groove region on the substrate;
providing a photoresist layer on a surface of the first insulation layer to be etched away from the first metal layer, and performing a patterning treatment on the photoresist layer to form a first etched groove and a second etched groove, wherein the first etched groove is located in the first groove region and is formed by recessing a surface of the photoresist layer away from the first insulation layer to be etched, and the second etched groove is located in the first via region and penetrates through the photoresist layer;
performing a first etching treatment on the base plate to be etched having the photoresist layer to remove at least a part of the first insulation layer to be etched in the first via region;
performing a thinning treatment on the photoresist layer, so that the first etched groove penetrates through the photoresist layer;
performing a second etching treatment on the base plate to be etched having the photoresist layer to form an array base plate comprising a first insulation layer, wherein the first insulation layer comprises a first groove located in the first groove region and a first via located in the first via region, the first groove is formed by recessing a surface of the first insulation layer away from the first metal layer, and the first via penetrates through the first insulation layer.

17. The method according to claim 16, wherein the first insulation layer to be etched comprises a first film layer and a second film layer located on a side of the first film layer facing the first metal layer,
in the step of performing the first etching treatment on the base plate to be etched having the photoresist layer, a part of the first film layer in the first via region is removed, a thickness of the part of the first film layer is n₁*H₁, wherein n₁ is a coefficient greater than 0 and less than 1, and H₁ is a thickness of the first film layer;
in the step of performing the second etching treatment on the base plate to be etched having the photoresist layer, at least a part of the first film layer in the first groove region is removed to form the first groove, and a remaining part of the first film layer and the second film layer in the first via region are removed to form the first via penetrating through the first film layer and the second film layer, a thickness of the remaining part of the first film layer is (1−n₁)*H₁; wherein the first film layer comprises a first sub-layer and a second sub-layer located on a side of the first sub-layer facing the substrate, and a thickness of the first sub-layer is n₁*H₁;
in the step of performing the first etching treatment on the base plate to be etched having the photoresist layer, the first sub-layer in the first via region is removed; and
in the step of performing the second etching treatment on the base plate to be etched having the photoresist layer, a part or all of the first sub-layer in the first groove region is removed, or the first sub-layer and at least a part of the second sub-layer in the first groove region are removed, so as to form the first groove; and the second sub-layer and the second film layer in the first via region are removed to form the first via penetrating through the first film layer and the second film layer.

18. The method according to claim 16, wherein the first insulation layer to be etched comprises a first film layer and a second film layer located on a side of the first film layer facing the first metal layer,
in the step of performing the first etching treatment on the base plate to be etched having the photoresist layer, the first film layer and the second film layer with a thickness of n₂*H₂ in the first via region are removed, wherein n₂ is a coefficient greater than 0 and less than 1, and H₂ is a thickness of the second film layer;
in the step of performing the second etching treatment on the base plate to be etched having the photoresist layer, at least a part of the first film layer in the first groove region is removed to form the first groove, and the second film layer with a thickness of (1−n₂)*H₂ in the first via region is removed to form the first via penetrating through the first film layer and the second film layer; wherein the second film layer comprises a third sub-layer and a fourth sub-layer located on a side of the third sub-layer facing the substrate, and a thickness of the fourth sub-layer is n₂*H₂;
in the step of performing the first etching treatment on the base plate to be etched having the photoresist layer, the first film layer and the third sub-layer in the first via region are removed; and
in the step of performing the second etching treatment on the base plate to be etched having the photoresist layer, at least a part of the first film layer in the first groove region is removed to form the first groove, and the fourth sub-layer in the first via region is removed to form the first via penetrating through the first film layer and the second film layer.

19. The method according to claim 16, wherein the first insulation layer to be etched comprises a first film layer and a second film layer located on a side of the first film layer facing the first metal layer,
in the step of performing the first etching treatment on the base plate to be etched having the photoresist layer, the first film layer in the first via region is removed;
in the step of performing the second etching treatment on the base plate to be etched having the photoresist layer, at least a part of the first film layer in the first groove region is removed to form the first groove, and the second film layer in the first via region is removed to form the first via penetrating through the first film layer and the second film layer.

20. The method according to claim 16, wherein
the base plate to be etched further comprises a first conductive layer and a second insulation layer, the first conductive layer is located on a side of the first metal layer facing the substrate and provided with a connection portion located in the first via region, and the second insulation layer is located between the first conductive layer and the first metal layer; and
the step of performing the second etching treatment on the base plate to be etched having the photoresist layer further comprises: removing the second insulation layer in the first via region to form a second via penetrating through the second insulation layer.
